(19) United States
(12) Patent Application Publication
(10) Pub. No.: US 2014/0077192 A1
(43) Pub. Date: Mar. 20, 2014

(54) ORGANIC LIGHT EMITTING DIODE

(71) Applicants: Tsung-Hsien Lin, Taichung City (TW); Hen-Ta Kang, Taichung City (TW); Chien-Chung Chen, Taichung City (TW)

(72) Inventors: Tsung-Hsien Lin, Taichung City (TW); Hen-Ta Kang, Taichung City (TW); Chien-Chung Chen, Taichung City (TW)

(73) Assignees: WINTEK CORPORATION, Taichung City (TW); DONGGUAN MASSTOP LIQUID CRYSTAL DISPLAY CO., LTD., Guangdong Province (CN)

(21) Appl. No.: 14/024,646

(22) Filed: Sep. 12, 2013

(30) Foreign Application Priority Data
Sep. 17, 2012 (TW) 101134026

(51) Int. Cl. H01L 51/52

(52) U.S. Cl. CPC H01L 51/5262
USPC 257/40

(57) ABSTRACT

An organic light emitting diode (OLED) has a plurality of light emitting regions. The OLED includes an anode layer, a cathode layer, an organic light emitting layer, and a wavelength shift layer. The organic light emitting layer is disposed between the anode layer and the cathode layer and correspondingly provides the light emitting regions with a plurality of emitted lights. Here, the organic light emitting layer has a fixed thickness. The wavelength shift layer is disposed outside the organic light emitting layer, the cathode layer, and the anode layer. A wavelength range at half-peak of combination of the emitted lights is wider than a wavelength range at half-peak of one of the lights.

### CROSS-REFERENCE TO RELATED APPLICATION

This application claims the priority benefit of Taiwan application serial no. 101134026, filed on Sep. 17, 2012. The entirety of the above-mentioned patent application is hereby incorporated by reference herein and made a part of this specification.

### BACKGROUND OF THE INVENTION

1. Field of the Invention

The invention relates to an organic light emitting diode (OLED), more particularly, the invention relates to an OLED with a relatively wide luminescence spectrum.

2. Description of Related Art

At present, flat panel displays, e.g., liquid crystal displays (LCD), organic light emitting diode (OLED) displays, plasma display panels (PDP), and field emission displays (FED) have become indispensible home appliances. The OLED displays are characterized by no viewing angle restriction, low production costs, high response speed (at least 100 times the response speed of the LCD), low power consumption, self-illumination, the direct current driving function applicable to portable devices, wide operating temperature range, lightness, and so on. Hence, the OLED displays are likely to replace the LCD and become the next-generation flat displays.

However, the lights respectively emitted from the OLEDs may have varying luminescence spectra on account of the process of the OLEDs, i.e., the color tone may alter even when each OLED displays the same color. Thereby, the issue of color shift may occur in the OLED display panels, which poses a negative impact on the display performance of the OLED display panels. Accordingly, it is rather important for designers of OLED display panels to reduce the color shift of the lights emitted from the OLEDs.

### SUMMARY OF THE INVENTION

The invention is directed to an organic light emitting diode (OLED) capable of expanding the width of luminescence spectra of emitted lights, so as to fix color shift on an OLED display panel.

In an embodiment of the invention, an OLED that has a plurality of light emitting regions is provided. The OLED includes an anode layer, a cathode layer, an organic light emitting layer, and a wavelength shift layer. The organic light emitting layer is disposed between the anode layer and the cathode layer and correspondingly provides the light emitting regions with a plurality of emitted lights. Here, the organic light emitting layer has a fixed thickness. The wavelength shift layer is disposed outside the organic light emitting layer, the cathode layer, and the anode layer. A wavelength range at half-peak of the combination of the emitted lights is wider than a wavelength range at half-peak of one of the emitted lights.

In view of the above, the wavelength ranges of the emitted lights corresponding to different light emitting regions are different from one another in the OLED described herein. Hence, a wavelength range at half-peak of the combination of the emitted lights is widened, so as to fix color shift in the OLED display panel.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic structural view illustrating an organic light emitting diode (OLED) according to a first embodiment of the invention.

FIG. 1B is a schematic view illustrating spectra of emitted lights depicted in FIG. 1A according to an embodiment of the invention.

FIG. 1C is a schematic view illustrating spectrum of integral emitted light depicted in FIG. 1A according to an embodiment of the invention.

FIG. 1D is a schematic structural view illustrating an OLED according to a second embodiment of the invention.

FIG. 2A is a schematic structural view illustrating an OLED according to a third embodiment of the invention.

FIG. 2B is a schematic structural view illustrating an OLED according to a fourth embodiment of the invention.

FIG. 3A is a schematic structural view illustrating the OLED according to the fifth embodiment of the invention.

FIG. 3B is a schematic structural view illustrating the OLED according to the sixth embodiment of the invention.

### DESCRIPTION OF EMBODIMENTS

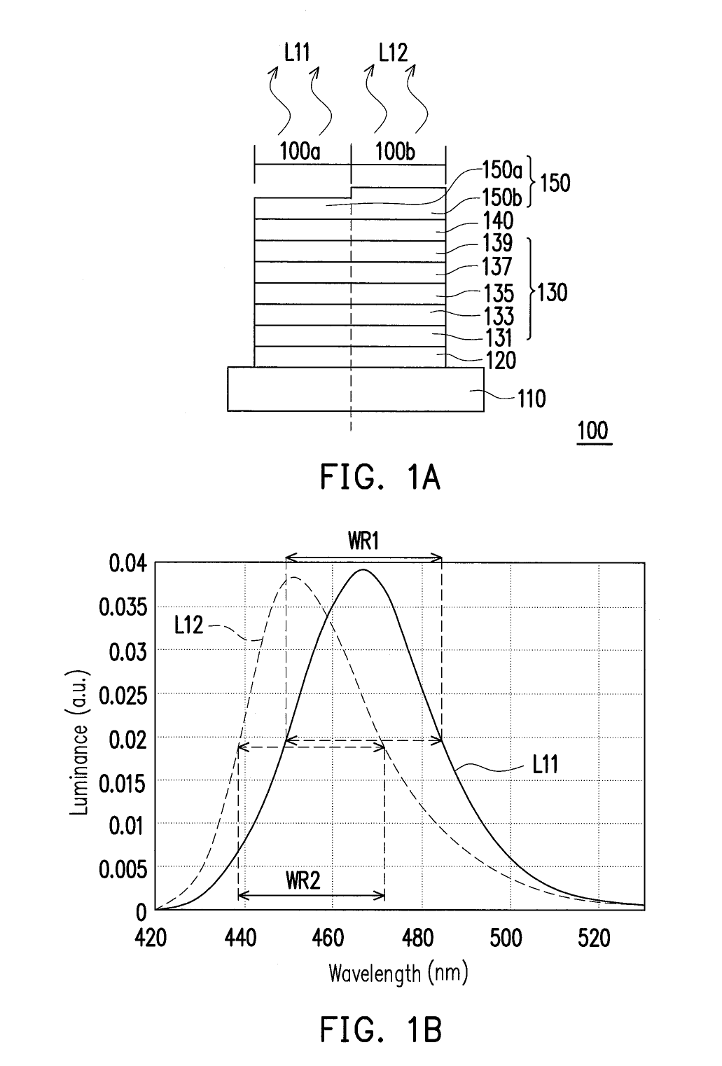

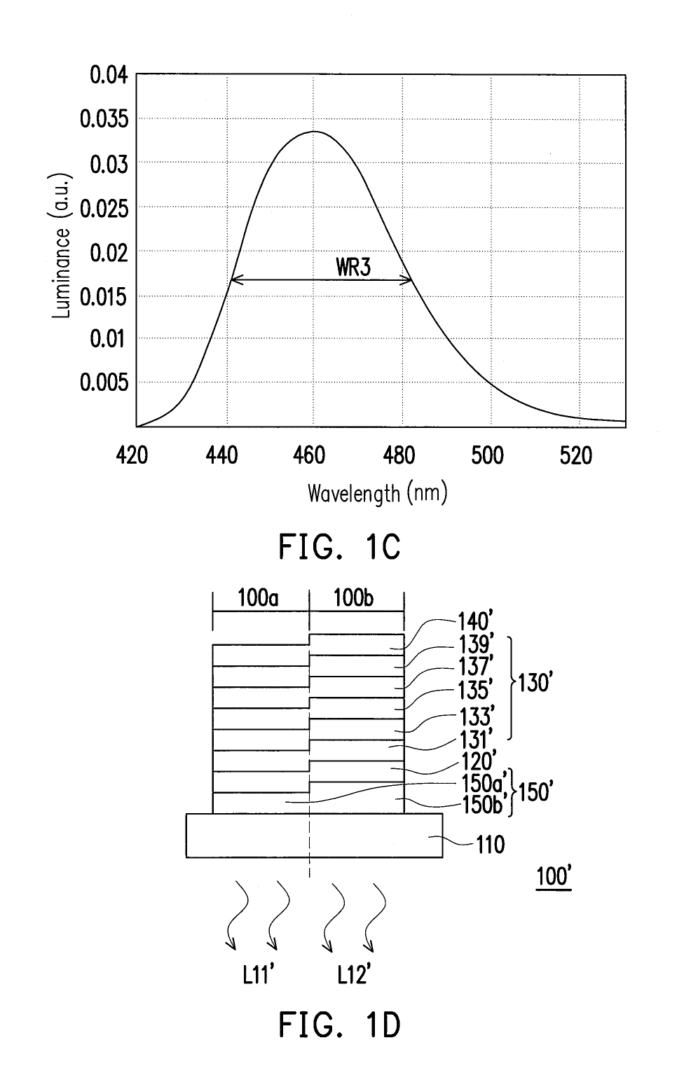

FIG. 1A is a schematic structural view illustrating an organic light emitting diode (OLED) according to a first embodiment of the invention. With reference to FIG. 1A, in the present embodiment, the OLED 100 is a top-emission type OLED and has a plurality of light emitting regions. Here, two light emitting regions 100a and 100b are exemplarily depicted in FIG. 1A. The OLED 100 includes a substrate 110, an anode layer 120, an organic light emitting layer 130, a cathode layer 140, and a wavelength shift layer (e.g., an overcoat layer 150). Here, the thickness of the organic light emitting layer 130 remains unchanged, i.e., the organic light emitting layer 130 has a fixed thickness. The organic light emitting layer 130 includes a hole injection layer 131, a hole transport layer 133, an emitting layer 135, an electron transport layer 137, and an electron injection layer 139. The overcoat layer 150 is divided into a plurality of optical shift portions (e.g., optical shift portions 150a and 150b) corresponding to the light emitting regions (e.g., the light emitting regions 100a and 100b), and the overcoat layer 150 may be made of an organic dielectric material or an inorganic dielectric material, which should however not be construed as a limitation to the invention.

As indicated in FIG. 1A, the substrate 110, the anode layer 120, the organic light emitting layer 130, the cathode layer 140, and the overcoat layer 150 are sequentially arranged from bottom to top in the OLED 100, i.e., the overcoat layer 150 is disposed on the anode layer 120, the organic light emitting layer 130, and the cathode layer 140. In other words, the anode layer 120 is disposed between the substrate 110 and the organic light emitting layer 130. The organic light emitting layer is disposed between the anode layer 120 and the cathode layer 140. The cathode layer 140 is disposed between the overcoat layer 150 and the organic light emitting layer 130.

The organic light emitting layer 130 includes the hole injection layer 131, the hole transport layer 133, the emitting layer 135, the electron transport layer 137, and the electron injection layer 139 that are sequentially arranged from bottom to top. Namely, the emitting layer 135 is disposed between the electron transport layer 137 and the hole transport layer 133. The electron injection layer 139 is disposed between the cathode layer 140 and the electron transport layer 137. The hole injection layer 131 is disposed between the anode layer 120 and the hole transport layer 133.

When the organic light emitting layer 130 is affected by an electric field of the anode layer 120 and the cathode layer 140, the organic light emitting layer 130 correspondingly provides the light emitting regions 100a and 100b with emitted lights, and peak wavelengths of the emitted lights of the organic light emitting layer 130 are shifted by the optical shift portions 150a and 150b, so as to generate emitted lights L11 and L12. Since the thicknesses of the optical shift portions 150a and 150b are different from each other, i.e., the peak wavelengths of the emitted lights are shifted to different extents, the peak wavelengths of the emitted light L11 and the emitted light L12 are different. Thereby, the wavelength range at half-peak of the emitted light L11 is different from the wavelength range at half-peak of the emitted light L12. After the luminescence spectra of the emitted lights L11 and L12 are combined, the wavelength range at half-peak of the emitted light of the OLED 100 is wider than the wavelength range at half-peak of the light L11 or L12. Thereby, color shift (e.g., color shift caused by variations in film thickness during the process and/or viewing angle color shift) in the OLED display panel containing the OLED 100 may be reduced, and the process window of film thickness of the OLED 100 may be relatively increased.

FIG. 1B is a schematic view illustrating spectra of emitted lights depicted in FIG. 1A according to an embodiment of the invention. FIG. 1C is a schematic view illustrating spectrum of integral emitted light depicted in FIG. 1A according to an embodiment of the invention. With reference to FIG. 1A and FIG. 1B, in the present embodiment, the overcoat layer 150 is assumed to be made of Sn0₂, the thickness of the optical shift portion 150a is 6 nm, the thickness of the optical shift portion 150b is 35 nm, and the area of the optical shift portion 150a is approximately equal to the area of the optical shift portion 150b.

As shown by the luminescence spectra of the emitted lights L11 and L12 in FIG. 1B, the wavelength range WR1 at half-peak of the emitted light L11 is partially overlapped with the wavelength range WR2 at half-peak of the emitted light L12, and the wavelength range WR1 is different from the wavelength range WR2. Here, the width of the wavelength range WR1 is approximately 35 nm, and the width of the wavelength range WR2 is approximately 33 nm.

In FIG. 1C which shows the luminescence spectrum of the integral emitted light in the OLED 100, after the emitted lights L11 and L12 are combined, the width of the wavelength range WR3 at half-peak is approximately 41 nm. Namely, after the emitted lights L11 and L12 are combined, the overall luminescence spectrum of integral emitted light in the OLED 100 is wider than the luminescence spectrum of the emitted light L11 or L12. Thereby, color shift in the OLED display panel containing the OLED 100 may be reduced.

FIG. 1D is a schematic structural view illustrating an OLED according to a second embodiment of the invention. With reference to FIG. 1A and FIG. 1D, in the present embodiment, the structure of the OLED 100′ is similar to the structure of the OLED 100, while the difference rests in that the OLED 100′ is a bottom-emission type OLED. That is, in the OLED 100′, the positions of the anode layer 120′, the organic light emitting layer 130′, the cathode layer 140′, and the wavelength shift layer (e.g., a buffer layer 150′) relative to the position of the substrate 110 differ from those in the OLED 100. As indicated in FIG. 1D, the substrate 110, the buffer layer 150′, the anode layer 120′, the organic light emitting layer 130′, and the cathode layer 140′ are sequentially arranged from bottom to top in the OLED 100′, i.e., the buffer layer 150′ is disposed between the substrate 110 and the cathode layer 140′. The buffer layer 150′ is also divided into a plurality of optical shift portions (e.g., optical shift portions 150a′ and 150b′) corresponding to the light emitting regions (e.g., the light emitting regions 100a and 100b). The structure of the organic light emitting layer 130′ is the same as that of the organic light emitting layer 130, i.e., the organic light emitting layer 130′ includes the hole injection layer 131′, the hole transport layer 133′, the emitting layer 135′, the electron transport layer 137′, and the electron injection layer 139′ that are sequentially arranged from bottom to top.

Besides, peak wavelengths of the emitted lights of the organic light emitting layer 130′ corresponding to the light emitting regions 100a and 100b are shifted by the optical shift portions 150a′ and 150b′, so as to generate emitted lights L11′ and L12′. Since the thicknesses of the optical shift portions 150a′ and 150b′ are different from each other, the wavelength ranges at half-peak of the emitted light L11′ and the emitted light L12′ are different. Therefore, if the overall luminescence spectrum of the OLED 100′ is observed, it is found that the wavelength range at half-peak of the emitted light of the OLED 100′ is wider than the wavelength range at half-peak of the light L11′or L12′. Thereby, color shift in the OLED display panel containing the OLED 100′ may be reduced, and the process window of film thickness of the OLED 100′ may be relatively increased.

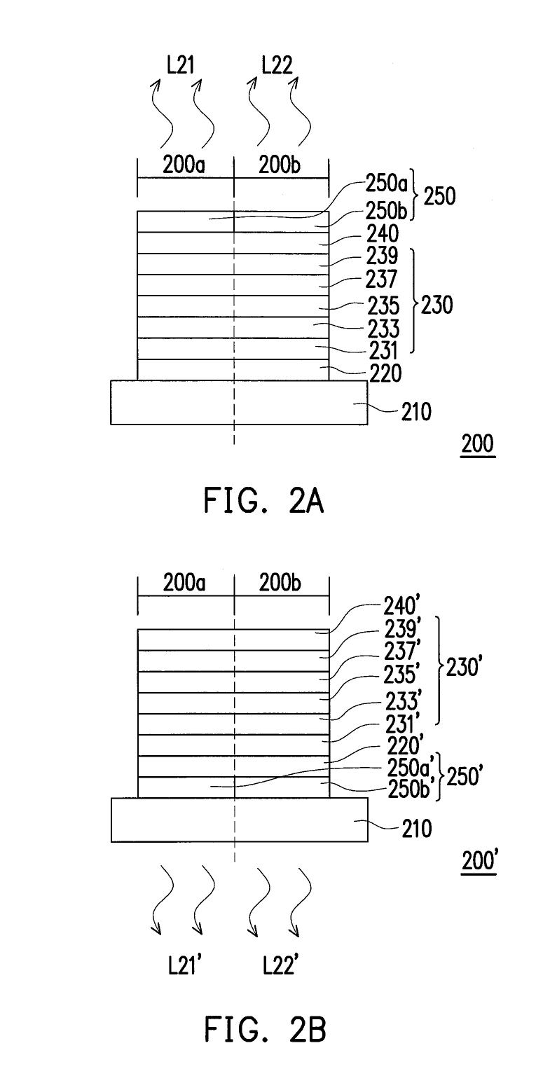

FIG. 2A is a schematic structural view illustrating an OLED according to a third embodiment of the invention. With reference to FIG. 2A, in the present embodiment, the OLED 200 is a top-emission type OLED and has a plurality of light emitting regions. Here, two light emitting regions 200a and 200b are exemplarily depicted in FIG. 2A. The OLED 200 includes a substrate 210, an anode layer 220, an organic light emitting layer 230, a cathode layer 240, and a wavelength shift layer (e.g., an overcoat layer 250). Here, the thickness of the organic light emitting layer 230 remains unchanged, i.e., the organic light emitting layer 230 has a fixed thickness. The organic light emitting layer 230 includes a hole injection layer 231, a hole transport layer 233, an emitting layer 235, an electron transport layer 237, and an electron injection layer 239. The overcoat layer 250 includes a plurality of optical shift layers (e.g., optical shift layers 250a and 250b) with different refractive indices, and the optical shift layers (e.g., the optical shift layers 250a and 250b) respectively correspond to the light emitting regions (e.g., the light emitting regions 200a and 200b) and are respectively in contact with the cathode layer 240.

As indicated in FIG. 2A, the substrate 210, the anode layer 220, the organic light emitting layer 230, the cathode layer 240, and the overcoat layer 250 are sequentially arranged from bottom to top in the OLED 200. The organic light emitting layer 230 includes the hole injection layer 231, the hole transport layer 233, the emitting layer 235, the electron transport layer 237, and the electron injection layer 239 that are sequentially arranged from bottom to top.

Besides, peak wavelengths of the emitted lights of the organic light emitting layer 230 corresponding to the light emitting regions 200a and 200b are shifted by the optical shift layers 250a and 250b, so as to generate emitted lights L21 and L22. Since the refractive indices of the optical shift layers 250a and 250b are different from each other, i.e., the peak wavelengths of the emitted lights are shifted to different extents, the wavelength ranges at half-peak of the emitted light L21 and the emitted light L22 are different. Therefore, if the overall luminescence spectrum of the OLED 200 is observed, it is found that the wavelength range at half-peak of the emitted light of the OLED 200 is wider than the wavelength range at half-peak of the light L21 or L22. Thereby, color shift in the OLED display panel containing the OLED 200 may be reduced, and the process window of film thickness of the OLED 200 may be relatively increased.

FIG. 2B is a schematic structural view illustrating the OLED according to the fourth embodiment of the invention. With reference to FIG. 2A and FIG. 2B, in the present embodiment, the structure of the OLED 200′ is similar to the structure of the OLED 200, while the difference rests in that the OLED 200′ is a bottom-emission type OLED. That is, in the OLED 200′, the positions of the anode layer 220′, the organic light emitting layer 230′, the cathode layer 240′, and the wavelength shift layer (e.g., a buffer layer 250′) relative to the position of the substrate 210 differ from those in the OLED 200. As indicated in FIG. 2B, the substrate 210, the buffer layer 250′, the anode layer 220′, the organic light emitting layer 230′, and the cathode layer 240′ are sequentially arranged from bottom to top in the OLED 200′. The buffer layer 250′ also includes a plurality of optical shift layers (e.g., optical shift layers 250a′ and 250b′) corresponding to the light emitting regions (e.g., the light emitting regions 200a and 200b). The structure of the organic light emitting layer 230′ is the same as that of the organic light emitting layer 230, i.e., the organic light emitting layer 230′ includes the hole injection layer 231′, the hole transport layer 233′, the emitting layer 235′, the electron transport layer 237′, and the electron injection layer 239′ that are sequentially arranged from bottom to top.

Besides, peak wavelengths of the emitted lights of the organic light emitting layer 230′ corresponding to the light emitting regions 200a and 200b are shifted by the optical shift layers 250a′ and 250b′, so as to generate emitted lights L21′ and L22′. Since the refractive indices of the optical shift layers 250a′ and 250b′ are different from each other, the wavelength ranges at half-peak of the emitted light L21′ and the emitted light L22′ are different. Therefore, if the overall luminescence spectrum of the OLED 200′ is observed, it is found that the wavelength range at half-peak of the emitted light of the OLED 200′ is wider than the wavelength range at half-peak of the light L21′ or L22′. Thereby, color shift in the OLED display panel containing the OLED 200′ may be reduced, and the process window of film thickness of the OLED 200′ may be relatively increased.

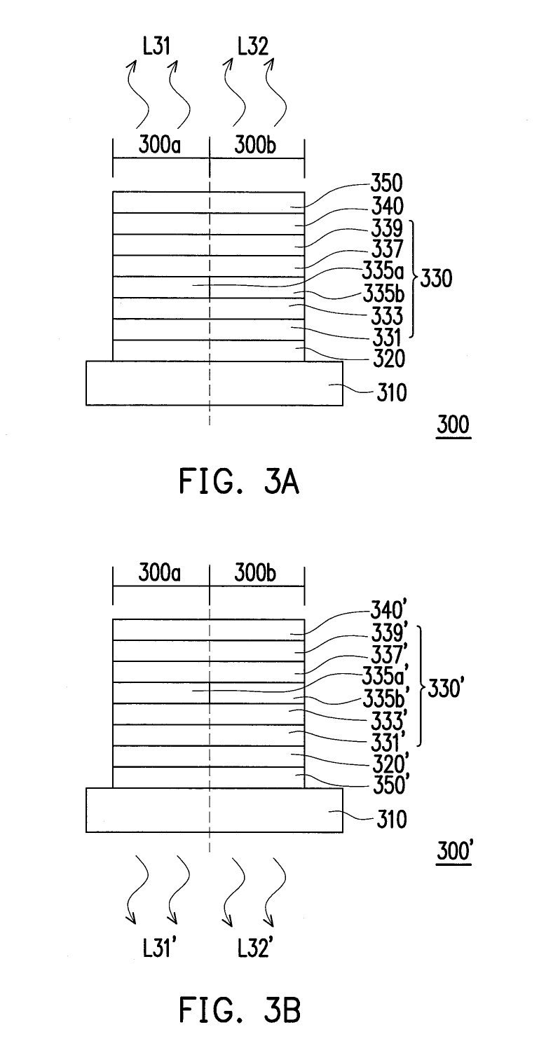

FIG. 3A is a schematic structural view illustrating the OLED according to the fifth embodiment of the invention. With reference to FIG. 3A, in the present embodiment, the OLED 300 is a top-emission type OLED and has a plurality of light emitting regions. Here, two light emitting regions 300a and 300b are exemplarily depicted in FIG. 3A. The OLED 300 includes a substrate 310, an anode layer 320, an organic light emitting layer 330, a cathode layer 340, and a wavelength shift layer (e.g., an overcoat layer 350). Here, the thickness of the organic light emitting layer 330 remains unchanged, i.e., the organic light emitting layer 330 has a fixed thickness.

The organic light emitting layer 330 includes a hole injection layer 331, a hole transport layer 333, a plurality of emitting layers (e.g., emitting layers 335a and 335b), an electron transport layer 337, and an electron injection layer 339. The emitting layers (e.g., the emitting layers 335a and 335b) are made of the same material but have different doped concentrations.

As indicated in FIG. 3A, the substrate 310, the anode layer 320, the organic light emitting layer 330, the cathode layer 340, and the overcoat layer 350 are sequentially arranged from bottom to top in the OLED 300. The organic light emitting layer 330 includes the hole injection layer 331, the hole transport layer 333, the emitting layers (e.g., the emitting layers 335b or 335a), the electron transport layer 337, and the electron injection layer 339 that are sequentially arranged from bottom to top.

The emitting layers 335a and 335b correspondingly provide the light emitting regions 300a and 300b with the emitted lights L31 and L32. Since the doped concentrations of the emitting layers 335a and 335b are different from each other, the peak wavelengths of the emitted light L31 and the emitted light L32 are different. Thereby, the wavelength range at half-peak of the emitted light L31 is different from the wavelength range at half-peak of the emitted light L32. Therefore, if the overall luminescence spectrum of the OLED 300 is observed, it is found that the wavelength range at half-peak of the emitted light of the OLED 300 is wider than the wavelength range at half-peak of the light L31 or L32. Thereby, color shift in the OLED display panel containing the OLED 300 may be reduced, and the process window of film thickness of the OLED 300 may be relatively increased.

FIG. 3B is a schematic structural view illustrating the OLED according to the sixth embodiment of the invention. With reference to FIG. 3A and FIG. 3B, in the present embodiment, the structure of the OLED 300′ is similar to the structure of the OLED 300, while the difference rests in that the OLED 300′ is a bottom-emission type OLED. That is, in the OLED 300′, the positions of the anode layer 320′, the organic light emitting layer 330′, the cathode layer 340′, and the wavelength shift layer (e.g., a buffer layer 350′) relative to the position of the substrate 310 differ from those in the OLED 300. As indicated in FIG. 3B, the substrate 310, the buffer layer 350′, the anode layer 320′, the organic light emitting layer 330′, and the cathode layer 340′ are sequentially arranged from bottom to top in the OLED 300′. The organic light emitting layer 330′ also includes a plurality of emitting layers (e.g., emitting layers 335a′ and 335b′) corresponding to the light emitting regions (e.g., the light emitting regions 300a and 300b). The structure of the organic light emitting layer 330′ is the same as that of the organic light emitting layer 330, i.e., the organic light emitting layer 330′ includes the hole injection layer 331′, the hole transport layer 333′, the emitting layers (e.g., the emitting layers 335b′ or 335a′), the electron transport layer 337′, and the electron injection layer 339′ that are sequentially arranged from bottom to top.

In addition, the emitting layers 335a′ and 335b′ correspondingly provide the light emitting regions 300a and 300b with the emitted lights L31′ and L32′. Since the doped concentrations of the emitting layers 335a′ and 335b′ are different from each other, the wavelength ranges at half-peak of the emitted light L31′ and the emitted light L32′ are different. Therefore, if the overall luminescence spectrum of the OLED 300′ is observed, it is found that the wavelength range at half-peak of the emitted light of the OLED 300′ is wider than the wavelength range at half-peak of the light L31′ or L32′. Thereby, color shift in the OLED display panel containing the OLED 300′ may be reduced, and the process window of film thickness of the OLED 300′ may be relatively increased.

In the previous embodiments, the anode layer (e.g., the anode layer 120, 120′, 220, 220′, 320, or 320′), the organic light emitting layer (e.g., the organic light emitting layer 130, 130′, 230, 230′, 330, or 330′), and the cathode layer (e.g., the cathode layer 140, 140′, 240, 240′, 340, or 340′) in the OLED (e.g., the OLED 100, 100′, 200, 200′, 300, or 300′) are sequentially arranged from bottom to top; however, in other embodiments, the anode layer (e.g., the anode layer 120, 120′, 220, 220′, 320, or 320′), the organic light emitting layer (e.g., the organic light emitting layer 130, 130′, 230, 230′, 330, or 330′), and the cathode layer (e.g., the cathode layer 140, 140′, 240, 240′, 340, or 340′) in the OLED (e.g., the OLED 100, 100′, 200, 200′, 300, or 300′) may be sequentially arranged from top to bottom. In this case, the hole injection layer (e.g., the hole injection layer 131, 131′, 231, 231′, 331, or 331′), the hole transport layer (e.g., the hole transport layer 133, 133′, 233, 233′, 333, or 333′), the emitting layer (e.g., the emitting layer 135, 135′, 235, 235′, 335, or 335′), the electron transport layer (e.g., the electron transport layer 137, 137′, 237, 237′, 337, or 337′), and the electron injection layer (e.g., the electron injection layer 139, 139′, 239, 239′, 339, or 339′) in the organic light emitting layer may be correspondingly adjusted to be sequentially arranged from top to bottom.

To sum up, the peak wavelengths of the emitted lights corresponding to different light emitting regions are different from one another in the OLED described herein; that is, the wavelength range at half-peak of one emitted light is different from the wavelength range at half-peak of another emitted light. Hence, if the overall luminescence spectrum of the OLED is observed, it is found that the wavelength range at half-peak of the emitted light of the OLED is wider than the wavelength range at half-peak of one of the lights, so as to fix color shift in the OLED display panel. Moreover, the overcoat layer or the buffer layer may be made of an inorganic dielectric material, such that the cost barrier of manufacturing the OLED may be lowered down.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. An organic light emitting diode having a plurality of light emitting regions and comprising:
an anode layer;
a cathode layer;
an organic light emitting layer disposed between the anode layer and the cathode layer, the organic light emitting layer providing the light emitting regions with a plurality of emitted lights and having a fixed thickness;
a wavelength shift layer disposed outside the cathode layer, the organic light emitting layer, and the anode layer, wherein a wavelength range at half-peak of the combination of the emitted lights is wider than a wavelength range at half-peak of one of the lights.

2. The organic light emitting diode as recited in claim 1, wherein the organic light emitting layer comprises:
an electron transport layer;
a hole transport layer; and
a plurality of emitting layers disposed between the electron transport layer and the hole transport layer, the emitting layers corresponding to the light emitting regions.

3. The organic light emitting diode as recited in claim 2, wherein doped concentrations of the emitting layers are different from one another.

4. The organic light emitting diode as recited in claim 2, wherein the organic light emitting layer further comprises:
an electron injection layer disposed between the cathode layer and the electron transport layer; and
a hole injection layer disposed between the anode layer and the hole transport layer.

5. The organic light emitting diode as recited in claim 1, wherein the wavelength shift layer comprises a plurality of optical shift layers respectively in contact with the cathode layer, and refractive indices of the optical shift layers are different from one another.

6. The organic light emitting diode as recited in claim 1, wherein the wavelength shift layer is divided into a plurality of optical shift portions corresponding to the light emitting regions, and thicknesses of the optical shift portions are different from one another.

7. The organic light emitting diode as recited in claim 1, further comprising a substrate, wherein the anode layer is disposed between the substrate and the organic light emitting layer, and the cathode layer is disposed between the wavelength shift layer and the organic light emitting layer.

8. The organic light emitting diode as recited in claim 1, further comprising a substrate, wherein the wavelength shift layer is disposed between the substrate and the anode layer.
